(19) United States
(12) Patent Application Publication
(10) Pub. No.: US 2007/0235738 A1
(43) Pub. Date: Oct. 11, 2007

(54) Nanowire light emitting device and method of fabricating the same

(75) Inventors: Young-gu Jin, Gyeonggi-do (KR); Hyo-sug Lee, Gyeonggi-do (KR); Sung-hoon Lee, Gyeonggi-do (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/224,286

(22) Filed: Sep. 13, 2005

(30) Foreign Application Priority Data
Sep. 13, 2004 (KR) 10-2004-0073086

(51) Int. Cl. H01L 33/00; H01L 21/00

(52) U.S. Cl. 257/79; 438/608; 438/22; 977/762

(57) ABSTRACT

A nanowire light emitting device and method of fabricating the same. The nanowire light emitting device includes: a substrate; a first electrode layer formed on the substrate; a plurality of nanowires vertically formed on the first electrode layer, the nanowire having a p-type doped portion and an n-type doped portion formed separately from each other on both sides thereof; a light emitting layer formed between the p-type doped portion and the n-type doped portion; and a second electrode layer formed on the nanowires, wherein the p-type doped portion is formed by chemically binding a radical having an only half-occupied outermost orbital shell to a corresponding surface of the respective nanowires so as to donate an electron to the radical.

### BACKGROUND OF THE INVENTION

This application claims the benefit of Korean Patent Application No. 10-2004-0073086, filed on Sep. 13, 2004, in the Korean Intellectual Property Office, the disclosure of which is incorporated herein in its entirety by reference.

1. Field of the Invention

The present invention relates to a nanowire light emitting device and a method of fabricating the same, and more particularly, to a nanowire light emitting device in which the nanowire has a p-type doped portion obtained by chemically binding a radical having an unpaired electron in its outermost orbital shell to a corresponding portion of the nanowire, and a method of fabricating the nanowire light emitting device.

2. Description of the Related Art

Although a light emitting diode (LED) made of gallium nitride (GaN) has high light emitting efficiency, a lattice mismatch problem with the substrate makes it difficult for use in producing a large size device.

Technologies using nanostructures for light emitting devices are being developed. Japanese Patent Publication No. Hei 10-326888 discloses a light emitting device comprising a nanowire made of silicon and a method of fabricating the light emitting device. After a catalytic layer such as gold is deposited on a substrate, a silicon nanowire is grown from the catalytic layer by flowing silicon tetrachloride (SiCl₄) gas into a reactor. The silicon nanowire light emitting device can be manufactured at a low cost. However, the silicon nanowire light emitting device has a low light emitting efficiency.

U.S. Patent Publication No. 2003/0168964 discloses a nanowire light emitting device having a p-n diode structure. In this case, the lower portion of the nanowire light emitting device is formed of an n-type nanowire and the upper portion is formed of a p-type nanowire, and the nanowire light emitting device emits light from the junction region of the two portions. Other components are added using a vapor phase-liquid phase-solid phase (VLS) method in order to fabricate the nanowire light emitting device having the p-n junction structure.

The nanowire light emitting device having the p-n junction structure is obtained by sequentially forming a p-type nanowire on an n-type nanowire, thus making it difficult to obtain a high quality p-n junction structure. That is, the semiconductor atom must be substituted with an impurity atom using ion implantation or diffusion in order to form the p-type nanowire. However, it is very difficult to obtain the p-type nanowire having a nano-sized diameter using this doping method.

In addition, when the nanowire is highly doped during its growth using a self-assembly method, the dopant may interfere with the growth of the nanowire.

Thus, there is a need for a method of forming a p-type nanowire by doping after the nanowire is formed.

### SUMMARY OF THE INVENTION

The present invention provides a nanowire light emitting device in which the nanowire has a p-type doped portion obtained by chemically binding a radical having an unpaired electron in its outermost orbital shell to a corresponding surface of the nanowire, and a method of fabricating the nanowire light emitting device.

According to a first aspect, the present invention provides a nanowire light emitting device comprising: a substrate; a first electrode layer formed on the substrate; a plurality of nanowires vertically formed on the first electrode layer, said nanowire having a p-type doped portion and an n-type doped portion formed separately from each other on both sides of the nanowire; a light emitting layer formed between the p-type doped portion and the n-type doped portion; and a second electrode layer formed on the nanowires, wherein the p-type doped portion is formed by chemically binding a radical having an only half-occupied outermost orbital shell to a corresponding surface of said nanowire so as to donate an electron to the radical.

The nanowire light emitting device may further comprise an insulating polymer filling a space between the nanowires formed on the first electrode layer.

The light emitting layer may be a boundary surface between the p-type doped portion and the n-type doped portion.

The light emitting layer may be a quantum well formed between the p-type doped portion and the n-type doped portion.

The nanowires may be made of a material selected from the group consisting of ZnO, SnO₂, In₂O₃, NiO and GaN.

The electrode layer which contacts the n-type doped portion may be made of a material selected from the group consisting of an n-type ZnO, Al-doped ZnO, In-doped ZnO, Ga-doped ZnO, ITO and an n-type GaN.

The radical may be selected from the group consisting of a halogen atom, NO, NO₂ and an oxygen (O) atom.

The radical may be obtained by decomposing at least one compound selected from the group consisting of a peroxide compound, an azo compound and a persulfate compound.

According to another aspect, the present invention provides a nanowire light emitting device comprising: a substrate; a first electrode layer which is n-type and formed on the substrate; p-type doped nanowires vertically formed on the first electrode layer, said nanowire being formed by chemically binding a radical having an only half-occupied outermost orbital shell to a surface of said nanowire so as to donate an electron to the radical; a light emitting layer formed between the first electrode layer and the p-type doped nanowire; and a second electrode layer formed on the p-type doped nanowires.

A bottom portion of the p-type doped nanowires which contacts the first electrode layer may be further n-type doped with the impurity of the first electrode layer by subjecting the substrate to thermal annealing.

According to yet another aspect, the present invention provides a method of fabricating a nanowire light emitting device, which comprises: forming a first electrode layer on a substrate; forming an n-type doped portion of nanowires vertically on the first electrode layer; forming an intrinsic portion of nanowires on the n-type doped portion of nanowires; p-type doping the intrinsic portion by chemically binding a radical having an only half-occupied outermost orbital shell to the intrinsic portion; and forming a second electrode layer on the nanowires.

The step of forming an n-type doped portion of nanowires may further comprise forming a quantum well on the n-type doped portion, and the intrinsic portion may be formed on the quantum well.

The step of p-type doping of the intrinsic portion may comprise: filling a first insulating polymer between the nanowires formed on the first electrode layer; etching the first insulating polymer to expose the intrinsic portion; and binding the radical to the exposed intrinsic portion.

The step of forming of the second electrode layer may comprise: filling a second insulating polymer between the nanowires exposed on the first insulating polymer; etching the second insulating polymer layer to expose upper ends of the nanowires; and forming a second electrode layer on the second insulating polymer layer.

According to yet another aspect, the present invention provides a method of fabricating a nanowire light emitting device, which comprises: forming a first electrode layer which is n-type on a substrate; forming nanowires on the first electrode layer; p-type doping the nanowires by binding a radical having an only half-occupied outermost orbital shell to the nanowires; and forming a second electrode layer on the nanowires.

The step of forming of the nanowires may further comprise penetrating an impurity of the first electrode layer into a lower portion of the nanowires by subjecting the substrate to momentary thermal annealing to form an n-type doped portion.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view illustrating a method of p-type doping a nanowire according to an embodiment of the present invention;

FIG. 2 is a view illustrating a principle of the p-type doping method according to an embodiment of the present invention;

FIGS. 3 through 5 are graphs showing the results of calculating the energy level of ZnO nanowire to which radicals chemically bind, based on the density functional theory (DFT);

FIGS. 6 through 9 are schematic cross-sectional views illustrating nanowire light emitting devices according to embodiments of the present invention;

FIG. 10 is a schematic view illustrating an apparatus for fabricating a nanowire light emitting device according to an embodiment of the present invention;

FIGS. 11A through 11G are views illustrating a method of fabricating a nanowire light emitting device according to an embodiment of the present invention;

FIG. 12 is a view illustrating a method of fabricating the nanowire light emitting device illustrated in FIG. 7;

FIGS. 13A through 13C are views illustrating a method of fabricating a nanowire light emitting device according to another embodiment of the present invention; and

FIG. 14 is a view illustrating a method of fabricating the nanowire light emitting device illustrated in FIG. 9.

### DETAILED DESCRIPTION OF THE INVENTION

A nanowire light emitting device and a method of fabricating the same according to embodiments of the present invention will be described in detail with reference to the attached drawings. However, the present invention should not be construed as being limited thereto.

FIG. 1 is a schematic view illustrating a method of p-type doping nanowires according to an embodiment of the present invention.

Referring to FIG. 1, when a nanowire 1 composed of ZnO and having a predetermined diameter, for example, 20-100 nm, comes in contact with a R—O—O—R′ molecule (wherein each of R and R′ is alkyl, halogenated alkyl, aryl, benzyl, or hydrogen and which can be the same as or different from each other) while its internal bond O—O is decomposed, the radicals O—R and O—R′ formed due to the decomposition chemically bind to a circumference of the nanowire 1. The radicals O—R and O—R′ have an unpaired electron in the outermost orbital shell thereof. The radicals chemically bind to the nanowire 1 while attracting an electron from the nanowire 1. Thus, a portion of the nanowire 1 from which the electron has escaped becomes p-type doped.

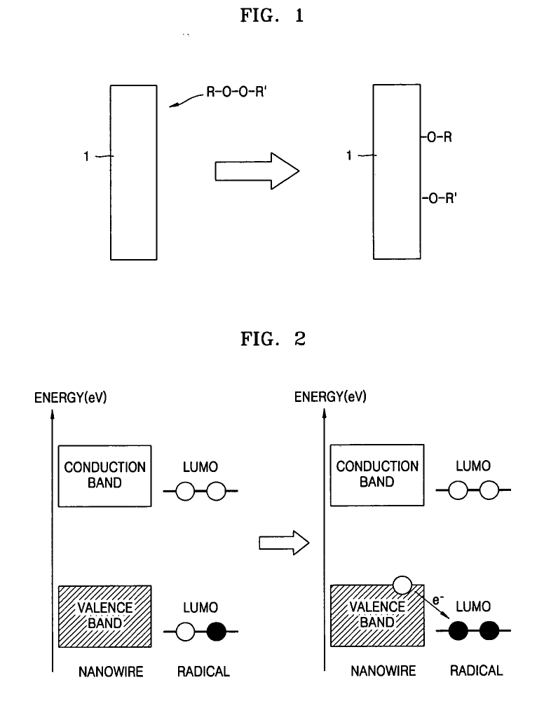

FIG. 2 is a view illustrating a principle of the p-type doping method according to an embodiment of the present invention.

Referring to FIG. 2, when a radical having an unpaired electron in the highest occupied molecular orbital (HOMO), which has a lower energy level than that of a valence band of the nanowire, is bound to a surface of a nanowire, an electron in the valence band moves to an empty space of the HOMO, thereby forming a hole in the nanowire. In FIG. 2, LUMO (lowest unoccupied molecular orbital) represents an orbital having the lowest energy level among unoccupied orbitals.

Energy levels of HOMOs of an ZnO nanowire and radicals are shown in Table 1.

TABLE 1

| | |
|---|---|
| F | −17.39 |
| OH | −12.98 |
| CH₃COO | −11.16 |
| NO₂ | −9.39 |
| NO | −9.26 |
| ZnO | −8.0 |

The unit of the numerical values in Table 1 is eV.

As seen from Table 1, since the energy level of the valence band in ZnO, which is used as a nanowire, is higher than that of the outermost orbital shell in the radicals, the electron of ZnO can easily move to the orbital of the radicals.

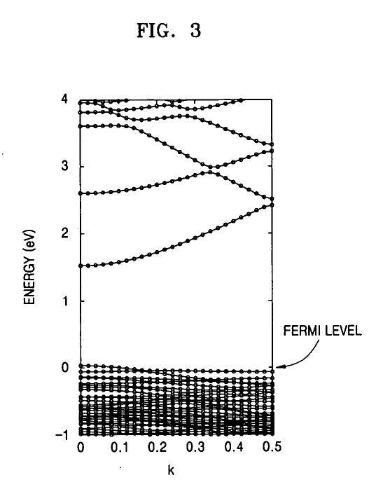

FIG. 3 is a graph showing the result of calculating the energy level of a ZnO nanowire to which a fluorine ion chemically binds, based on the density functional theory (DFT). It can be seen from FIG. 3 that the energy level of the valence band in the ZnO nanowire to which a fluorine ion binds is higher than the Fermi level, and thus, a hole can be formed in the nanowire. That is, an electron escapes from the ZnO nanowire, and thus, the ZnO nanowire becomes p-type doped. In FIG. 3, the x-axis represents a momentum space (k).

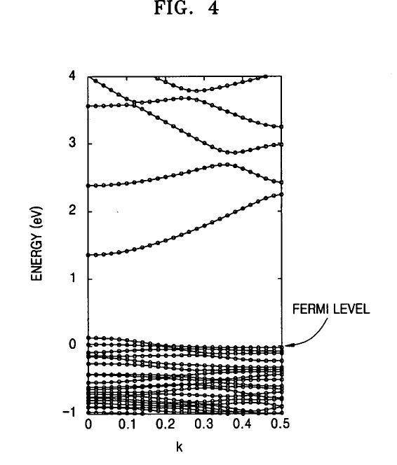

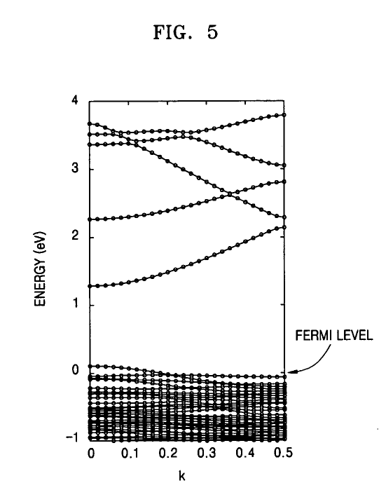

FIGS. 4 and 5 are graphs showing the energy levels of a product of a ZnO nanowire to which OH chemically binds and a product of a ZnO nanowire to which CH₃COO chemically binds, respectively. Both products exhibit a p-type doping property.

Although a ZnO nanowire is exemplified above, the nanowire for use in the present invention is not necessarily limited thereto. For example, a transparent conducting oxide which has a band gap having a wide energy gap between a conduction band and a valence band, such as SnO₂, In₂O₃, and NiO, or a nanowire composed of GaN may be used as the nanowire.

The radical for use in the present invention is not limited to F, OH, and CH₃COO. The nanowire may be p-type doped with NO, NO₂ and O, which have an unpaired electron in the outermost orbital shell.

The radical may be obtained by decomposing a peroxide compound (R—COO—OOC—R′ or R—O—O—R′), an azo compound (R—N═N—R′), or a persulfate compound (R—S—S—R or MxSyOz), wherein each of R and R′ is alkyl, halogenated alkyl, aryl, benzyl, or hydrogen and which can be the same as or different from each other, M is an alkali metal, and each of x, y, and z represents an integer. When these compounds are subjected to a thermal reaction, internal chemical bonds are broken, thereby forming radicals, which are used in the p-type doping.

For example, for the peroxide compound having the structure of R—O—O—R′, the O—O bond is broken to form RO⁻ and R′O⁻. For the azo compound, N—N is changed into N₂ gas and the remaining portion becomes a radical.

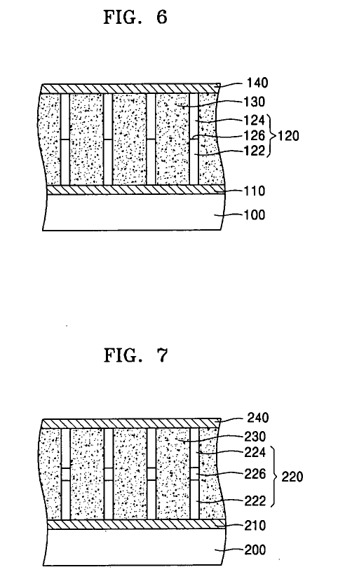

FIG. 6 is a schematic cross-sectional view illustrating a nanowire light emitting device according to an embodiment of the present invention.

Referring to FIG. 6, a conductive layer (a first electrode layer) 110 is formed on a substrate 100 and a plurality of nanowires 120 are substantially vertically formed on the conductive layer 110. A space between the nanowires 120 is filled with an insulating polymer 130 and a conductive layer (a second electrode layer) 140 is formed on the nanowires 120.

The nanowires 120 are composed of an n-type doped portion 122 and a p-type doped portion 124.

A silicon wafer, a sapphire wafer, a ZnO wafer, an ITO wafer, or a flat and thin metal film may be used as the substrate 100. A transparent substrate may be used for fabricating the light emitting device.

The first electrode layer 110 may be formed of an n-type electrode, thus improving its lattice matching property with an n-type doped nanowire. The n-type electrode may be made of an n-type ZnO, Al-doped ZnO, In-doped ZnO, Ga-doped ZnO, ITO, or an n-type GaN. The second electrode layer 140 may be formed of gold or platinum by deposition. An adhesive layer of nickel may be formed on the nanowires 120 before the deposition of gold or platinum.

The nanowires 120 have a wide band gap and may be made of a transparent conducting oxide, such as ZnO, SnO₂, In₂O₃, NiO, or GaN, etc. The nanowires 120 can emit two ultraviolet rays and the color of the light emitted from the nanowires 120 can be changed by injecting impurities into the nanowires 120. For example, when cobalt and indium are injected into ZnO and GaN, respectively, they emit blue light. When a metal impurity, such as, zinc is injected into ZnO, it emits yellow or white light. The nanowires 120 may have a diameter of about 20-100 nm and a length of about 0.5-1 μm.

The nanowires 120 have a p-n junction structure comprising the n-type doped portion 122 and the p-type doped portion 124 The reference numeral 126 denotes a boundary surface between the n-type doped portion 122 and the p-type doped portion 124, the boundary surface being a light emitting layer.

The n-type doped portion 122 is formed by flowing Al or Ga in a gaseous state together with a nanowire material in a gaseous state into a vacuum chamber during the growth of the nanowires. When the nanowires are made of an oxide, the n-type nano material can be formed by lowering the concentration of an oxygen source atom.

The p-type doped portion 124 is formed by chemically binding an atomic or molecular radical having an unpaired electron in its outermost orbital shell to a circumference of the nanowires 120. The radical which binds to the p-type doped portion 124 is formed by breaking a bond in a peroxide compound, an azo compound, and a persulfate compound, etc., as described above. The p-type doped portion 124 donates an electron to the radical and forms a hole on a surface of the corresponding portion of the nanowire.

The insulating polymer 130 prevents electrical contact between the nanowires 120. Polymethyl methacrylate (PMMA) photoresist or resin may be used as the insulating polymer 130.

The operation of the light emitting device having the above structure will be described in detail with reference to the attached drawings.

First, when a negative voltage is applied to the first electrode layer 110 which is connected to the n-type doped portion 122 of the nanowires 120 and a positive voltage is applied to the second electrode layer 140 which is connected to the p-type doped portion 124 of the nanowires 120, electrons in the n-type doped portion 122 and holes in the p-type doped portion 124 recombine with each other at the boundary surface 126, thus emitting light. The light emitted from the boundary surface 126 is transmitted through a transparent electrode layer, for example, the first electrode layer 110, and emitted outside the device.

FIG. 7 is a schematic cross-sectional view illustrating a nanowire light emitting device according to another embodiment of the present invention. Like reference numerals as in FIG. 6 refer to like elements, and detailed description thereof will not be repeated.

Referring to FIG. 7, a conductive layer (a first electrode layer) 210 is formed on a substrate 200 and a plurality of nanowires 220 are substantially vertically formed on the conductive layer 210. Spaces between the nanowires 220 are filled with an insulating polymer 230 and a conductive layer (a second electrode layer) 240 is formed on the nanowires 220.

The nanowires 220 are composed of an n-type doped portion 222, a p-type doped portion 224, and a quantum well 226 which is interposed between the n-type doped portion 222 and the p-type doped portion 224. The quantum well 226 is a light emitting layer. Such a light emitting structure has a p-i-n junction structure. In the light emitting device having the above structure, when a direct voltage is applied to both ends of the nanowires 120 to cause a current to flow through the nanowires, light is emitted from the quantum well 226.

The quantum well 226 is formed by injecting Cd or Mg into a reaction system during formation of the nanowires 220. When the nanowires 220 are made of ZnO, a CdZnO or MgZnO layer is formed as the quantum well 226. The quantum well 226 may also be a multiple quantum wells in which alternating CdZnO and MgZnO layers are formed, each having a height of about 5 nm.

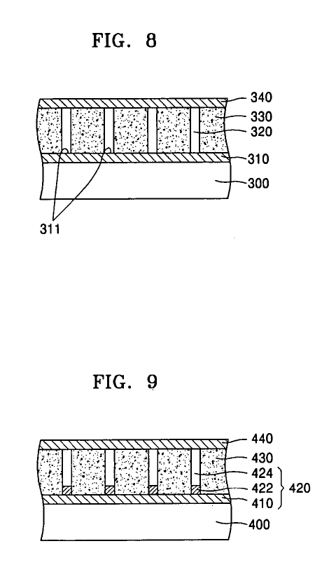

FIG. 8 is a schematic cross-sectional view illustrating a nanowire light emitting device according to yet another embodiment of the present invention. Like reference numerals as in FIG. 6 refer to like elements, and detailed description thereof will not be repeated.

Referring to FIG. 8, a conductive layer (a first electrode layer) 310 is formed on a substrate 300 and a plurality of nanowires 320 are substantially vertically formed on the conductive layer 310. Spaces between the nanowires 320 are filled with an insulating polymer 330, and a conductive layer (a second electrode layer) 340 is formed on the nanowires 320.

The nanowires 320 are p-type doped by chemically binding a radical having an only half-occupied outermost orbital shell to the nanowires 320.

The first electrode layer 310 may be formed of an n-type electrode. The n-type electrode may be made of an n-type ZnO, Al-doped ZnO, In-doped ZnO, Ga-doped ZnO, ITO, or an n-type GaN. The first electrode layer 310 may function as an n-type doped portion. When a direct voltage is applied to the first electrode layer 310 and the second electrode layer 340 to cause a current to flow, light is emitted from a boundary surface 311 between the first electrode layer 310 and the nanowires 320.

The fabricating process of the light emitting device illustrated in FIG. 8 is understood from the above description.

FIG. 9 is a schematic cross-sectional view illustrating a nanowire light emitting device according to yet another embodiment of the present invention. Like reference numerals as in FIG. 6 refer to like elements, and their detailed descriptions will not be repeated.

Referring to FIG. 9, a conductive layer (a first electrode layer) 410 is formed on a substrate 400 and a plurality of nanowires 420 are substantially vertically formed on the conductive layer 410. Spaces between the nanowires 420 are filled with an insulating polymer 430 and a conductive layer (a second electrode layer) 440 is formed on the nanowires 420.

The first electrode layer 410 may be formed of an n-type electrode. The n-type electrode may be made of an n-type ZnO, Al-doped ZnO, In-doped ZnO, Ga-doped ZnO, ITO or an n-type GaN.

The nanowires 420 are comprised of the n-type doped portion 422 and the p-type doped portion 424. The n-type doped portion 422 may be obtained by subjecting the substrate 400 to rapid thermal annealing, for example, at 1000° C. for 1 minute or less, to penetrate the impurity of the first electrode layer 410 into a lower portion of the nanowires 420. The n-type doped portion 422 can increase light emitting efficiency by moving the position of the p-n junction region 311 of FIG. 8 upwards.

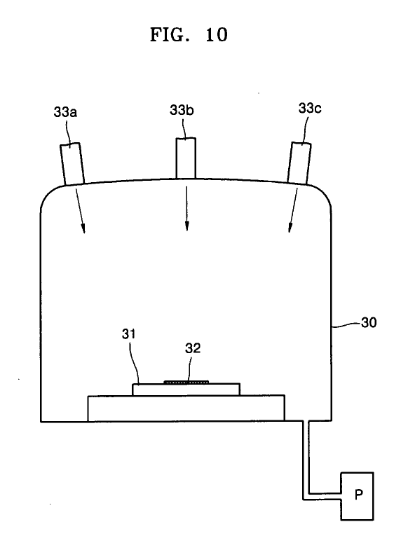

FIG. 10 is a schematic view illustrating an apparatus for fabricating a nanowire light emitting device according to an embodiment of the present invention. Referring to FIG. 10, a chamber 30 contains a substrate holder 31 and a substrate 32 is placed on the substrate holder 31. The reference letter P represents a vacuum pump, which can be used to eliminate impurities in the chamber 30. The reference numerals 33a, 33b and 33c represent gas inlets and the amount of a gas supplied to the chamber 30 can be optionally controlled. The temperature of the chamber 30 can be controlled to a predetermined temperature using a temperature controlling apparatus (not shown).

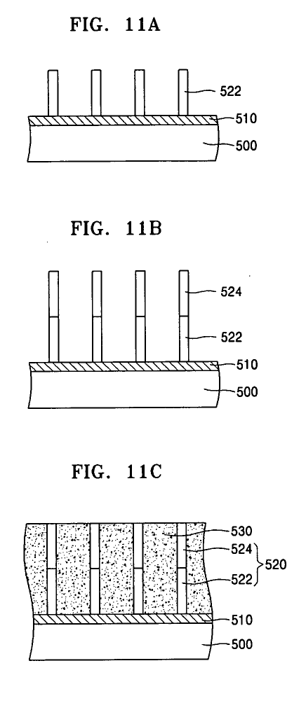

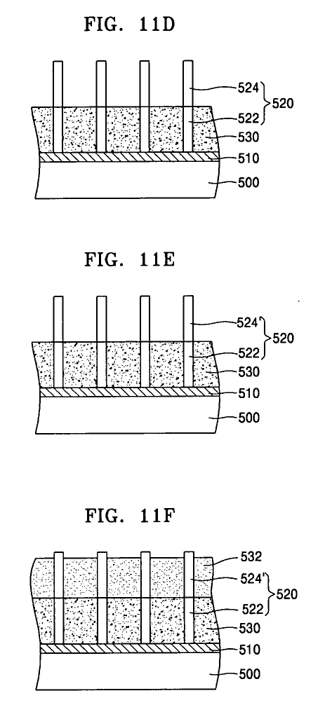

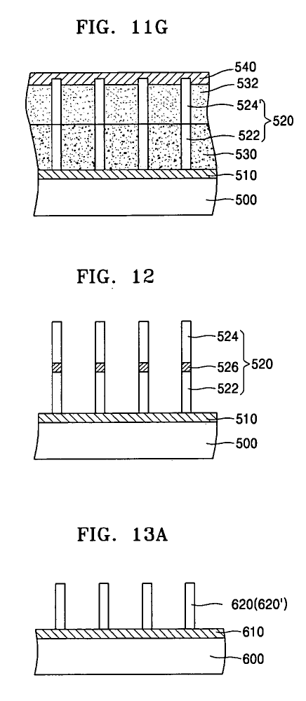

FIGS. 11A through 11G are views illustrating a method of fabricating a nanowire light emitting device according to a further embodiment of the present invention.

Referring to FIG. 11A, a first conductive layer 510 is deposited on a sapphire substrate 500 which is placed in the vacuum chamber (reference numeral 30 in FIG. 10). The first conductive layer 510 may be made of an n-type ZnO, Al-doped ZnO, In-doped ZnO, Ga-doped ZnO, ITO, or an n-type GaN. N-type nanowires 522 having a length of about 0.5 μm are formed on the first conductive layer 510 using a metal-organic-vapor phase epitaxy (MOVPE) method. The nanowires 522 may be formed of ZnO using diethyl-zinc (DEZn) and oxygen as a reaction source in the vacuum chamber. The n-type ZnO nanowires 522 are formed by flowing Al or Ga in a gaseous state together with a nanowire material in a gaseous state into a vacuum chamber during growth of the nanowires 522. When the nanowires 522 are made of an oxide, the n-type nano material can be formed by lowering the concentration of an oxygen source. The nanowires 522 may be formed using a conventional vapor phase-liquid phase-solid phase (VLS) method, a self-assembly method, or a method using a metal catalytic layer, but not being limited thereto.

Referring to FIG. 11B, intrinsic nanowires 524 are formed to have a length of about 0.5 μm on the n-type nanowires 522.

Referring to FIG. 11C, spaces between the nanowires 520 are filled with an insulating polymer, for example, a photoresist 530, on the first electrode layer 510 by spin-coating.

Referring to FIG. 11D, a portion of the photoresist 530 in the upper portion of the nanowires 520 is removed by ashing with an oxygen plasma or by wet etching. Only the intrinsic portion 524 of the nanowires is exposed.

Referring to FIG. 11E, a p-type doping molecule which can be decomposed to a radical having an unpaired electron in its outermost orbital shell is introduced into the vacuum chamber. For example, a source of a halogen molecule, NO, NO₂, or O is introduced into the vacuum chamber and decomposed to halogen atom, NO, NO₂, or O, which is bound to a circumference of the intrinsic portion 524, thereby making the intrinsic portion 524 into the corresponding p-type doped portion 524′.

In the p-type doping method, the p-type doped portion 524′ may be formed by coating a peroxide compound, an azo compound, or a persulfate compound on the circumference of the intrinsic portion 524, and then, decomposing the coated compound by heating the substrate 500 at 60-80° C. to form a radical molecule.

Referring to FIG. 11F, spaces between the p-type doped portions 524′ exposed on the photoresist 530 are filled with a thin photoresist 532 by spin-coating. Then, the photoresist 532 between the nanowires 520 is selectively removed by ashing with an oxygen plasma or by wet etching to expose the upper portion of the p-type doped portion 524′.

Referring to FIG. 11G, a second conductive layer 540 is deposited on the photoresist 532 to cover the exposed nanowires 520.

The light emitting device fabricated using the above process has the p-n junction structure illustrated in FIG. 6.

As illustrated in FIG. 12, in the light emitting device having the quantum well illustrated in FIG. 7, the quantum well 526 is formed on the n-type doped portion 522 by injecting Cd or Mg as well as the nanowire source into a reacting system. When the nanowires 520 are made of ZnO, a layer of CdZnO or MgZnO is formed as the quantum well 526. The quantum well 526 may also be a multiple quantum well in which alternating CdZnO and MgZnO layers are formed, each having a height of about 5 nm. The intrinsic portion 524 is formed by growing the nanowires on the quantum well 526. The subsequent process for forming the p-type doped portion is similar to the above-mentioned method and a detailed description thereof will not be repeated.

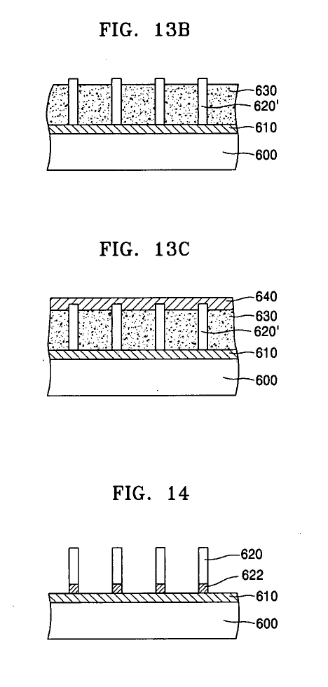

FIGS. 13A through 13C are views illustrating a method of fabricating a nanowire light emitting device according to a further embodiment of the present invention.

Referring to FIG. 13A, a first conductive layer 610 is deposited on a sapphire substrate 600. The first conductive layer 610 may be made of an n-type ZnO, Al-doped ZnO, In-doped ZnO, Ga-doped ZnO, ITO, or an n-type GaN. Nanowires 620 having a length of about 1 μm are formed on the first conductive layer 610 using a MOVPE method. The nanowires 620 may be formed of ZnO using diethyl-zinc (DEZn) and oxygen as a reaction source in the vacuum chamber.

Then, a p-type doping molecule which can be decomposed into a radical having an unpaired electron in the outermost orbital shell is introduced into the vacuum chamber. For example, a source of a halogen molecule, NO, NO₂, or O is introduced in the vacuum chamber and decomposed to halogen atom, NO, NO₂, or O, which is bound to a circumference of the intrinsic portion 620, thereby making the intrinsic portion 620 into the p-type doped portion 620′.

In the p-type doping method, the p-type doped portion 620′ may be formed by coating a peroxide compound, an azo compound, or a persulfate compound to the circumference of the intrinsic portion 620, and then, decomposing the coated compound by heating the substrate 600 at 60-80° C. to form a radical.

Referring to FIG. 13B, spaces between the p-type doped portions 620′ are filled with a thin photoresist 630 on the first electrode layer 610 by spin-coating. Then, the photoresist 630 is selectively removed by ashing with an oxygen plasma or by wet etching to expose the upper portion of the p-type doped portion 620′.

Referring to FIG. 13C, a second conductive layer 640 is deposited on the photoresist 630 to cover the exposed nanowires 620′.

The light emitting device fabricated using the above process has the p-n junction structure illustrated in FIG. 8.

The light emitting device having the structure illustrated in FIG. 9 can be fabricated by forming nanowires (see FIG. 13A) and subjecting the substrate 600 to rapid thermal annealing, for example, at 1000° C. for 1 minute or less, to penetrate the impurity of the first electrode layer 610 into a lower portion of the nanowires 620, thus obtaining an n-type doped portion 622, as illustrated in FIG. 14. The n-type doped portion 622 can increase light emitting efficiency by moving the position of the p-n junction region illustrated in FIG. 8 upwards. The subsequent process for fabricating the light emitting device is similar to that described above and a detailed description thereof will not be repeated.

As explained above, the nanowire light emitting device according to the present invention comprises a homogenous junction obtained by easily forming a p-type doped portion, the resulting device has high light emitting efficiency and can be mass-produced because lattice matching with a substrate is excellent. Also, the nanowire light emitting device can be directly applied to the manufacture of flat displays because it can be produced as a large size device.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A nanowire light emitting device comprising:
a substrate;
a first electrode layer formed on the substrate;
a plurality of nanowires vertically formed on the first electrode layer, said nanowire having a p-type doped portion and an n-type doped portion formed separately from each other on both sides of the nanowire;
a light emitting layer formed between the p-type doped portion and the n-type doped portion; and
a second electrode layer formed on the nanowires,
wherein the p-type doped portion is formed by chemically binding a radical having a half-occupied outermost orbital shell to a corresponding surface of said nanowire so as to donate an electron to the radical.

2. The device of claim 1, further comprising an insulating polymer filling a space between the nanowires formed on the first electrode layer.

3. The device of claim 1, wherein the light emitting layer is a boundary surface between the p-type doped portion and the n-type doped portion.

4. The device of claim 1, wherein the light emitting layer is a quantum well formed between the p-type doped portion and the n-type doped portion.

5. The device of claim 1, wherein the nanowires are made of a material selected from the group consisting of ZnO, SnO₂, In₂O₃, NiO and GaN.

6. The device of claim 1, wherein the electrode layer which contacts the n-type doped portion is made of a material selected from the group consisting of an n-type ZnO, Al-doped ZnO, In-doped ZnO, Ga-doped ZnO, ITO and an n-type GaN.

7. The device of claim 1, wherein the radical is selected from the group consisting of a halogen atom, NO, NO₂ and an oxygen (O) atom.

8. The device of claim 1, wherein the radical is obtained by decomposing at least one compound selected from the group consisting of a peroxide compound, an azo compound and a persulfate compound.

9. The device of claim 8, wherein the radical has at least one component selected from the group consisting of an alkyl group, an aryl group, a benzyl group, hydrogen and an alkali metal.

10. A nanowire light emitting device comprising:
a substrate;
a first electrode layer which is n-type and formed on the substrate;
p-type doped nanowires vertically formed on the first electrode layer, said nanowire being formed by chemically binding a radical having a half-occupied outermost orbital shell to a surface of said nanowire so as to donate an electron to the radical;
a light emitting layer formed between the first electrode layer and the p-type doped nanowire; and
a second electrode layer formed on the p-type doped nanowires.

11. The device of claim 10, further comprising an insulating polymer filling a space between the nanowires formed on the first electrode layer.

12. The device of claim 10, wherein the light emitting layer is a boundary surface between the p-type doped portion and the n-type doped portion.

13. The device of claim 10, wherein a bottom portion of the p-type doped nanowires which contacts the first electrode layer is further n-type doped with an impurity of the first electrode layer by subjecting the substrate to thermal annealing.

14. The device of claim 10, wherein the nanowires are made of a material selected from the group consisting of ZnO, SnO₂, In₂O₃, NiO and GaN.

15. The device of claim 10, wherein the first electrode layer is made of a material selected from the group consisting of an n-type ZnO, Al-doped ZnO, In-doped ZnO, Ga-doped ZnO, ITO and an n-type GaN.

16. The device of claim 10, wherein the radical is selected from the group consisting of a halogen atom, NO, NO₂ and an oxygen (O) atom.

17. The device of claim 10, wherein the radical is obtained by decomposing at least one compound selected from the group consisting of a peroxide compound, an azo compound and a persulfate compound.

18. The device of claim 17, wherein the radical has at least one component selected from the group consisting of an alkyl group, an aryl group, a benzyl group, hydrogen and an alkali metal.

19. A method of fabricating a nanowire light emitting device, which comprises:
forming a first electrode layer on a substrate;
forming an n-type doped portion of nanowires vertically on the first electrode layer;
forming an intrinsic portion of nanowires on the n-type doped portion of nanowires;
p-type doping the intrinsic portion by chemically binding a radical having a half-occupied outermost orbital shell to the intrinsic portion; and
forming a second electrode layer on the nanowires.

20. The method of claim 19, wherein the step of forming an n-type doped portion of nanowires further comprises forming a quantum well on the n-type doped portion, and
the intrinsic portion is formed on the quantum well.

21. The method of claim 19, wherein the step of p-type doping the intrinsic portion comprises:
filling a first insulating polymer between the nanowires formed on the first electrode layer;
etching the first insulating polymer to expose the intrinsic portion; and
binding the radical to the exposed intrinsic portion.

22. The method of claim 21, wherein the step of forming a second electrode layer comprises:
filling a second insulating polymer between the nanowires exposed on the first insulating polymer;
etching the second insulating polymer layer to expose upper ends of the nanowires; and
forming a second electrode layer on the second insulating polymer layer.

23. The method of claim 19, wherein the nanowires are made of a material selected from the group consisting of ZnO, SnO₂, In₂O₃, NiO and GaN.

24. The method of claim 19, wherein the first electrode layer is made of a material selected from the group consisting of an n-type ZnO, Al-doped ZnO, In-doped ZnO, Ga-doped ZnO, ITO and an n-type GaN.

25. The method of claim 19, wherein said binding of a radical to the intrinsic portion is performed by blowing a gaseous source comprising at least one species selected from the group consisting of a halogen atom, NO, NO₂ and an oxygen (O) atom into a vacuum chamber.

26. The method of claim 21, wherein said binding of a radical onto the intrinsic portion comprises:
coating at least one compound selected from a group consisting of a peroxide compound, an azo compound and a persulfate compound onto a circumference of the respective nanowires; and
decomposing a bond in the compound by heating the substrate to form the radical.

27. The method of claim 26, wherein the radical has at least one component selected from a group consisting of an alkyl group, an aryl group, a benzyl group, hydrogen and an alkali metal.

28. A method of fabricating a nanowire light emitting device, which comprises:
forming a first electrode layer which is n-type on a substrate;
forming nanowires on the first electrode layer;
p-type doping the nanowires by binding a radical having a half-occupied outermost orbital shell to the nanowires; and
forming a second electrode layer on the nanowires.

29. The method of claim 28, wherein the step of forming nanowires further comprises penetrating an impurity of the first electrode layer into a lower portion of the nanowires by subjecting the substrate to momentary thermal annealing to form an n-type doped portion.

30. The method of claim 28, wherein the step of forming a second electrode layer comprises:
filling an insulating polymer between the nanowires on the first electrode layer;
etching the insulating polymer layer to expose upper ends of the nanowires; and
forming the second electrode layer on the insulating polymer layer.

31. The method of claim 28, wherein the nanowires are made of a material selected from a group consisting of ZnO, SnO₂, In₂O₃, NiO and GaN.

32. The method of claim 28, wherein the first electrode layer is made of a material selected from a group consisting of an n-type ZnO, Al-doped ZnO, In-doped ZnO, Ga-doped ZnO, ITO and an n-type GaN.

33. The method of claim 28, wherein said binding of a radical is performed by blowing a gaseous source comprising at least one species selected from the group consisting of a halogen atom, NO, NO₂ and an oxygen (O) atom into a vacuum chamber.

34. The method of claim 28, wherein said binding of a radical comprises:
coating at least one compound selected from the group consisting of a peroxide compound, an azo compound and a persulfate compound onto a circumference of the respective nanowires; and
decomposing a bond in the compound by heating the substrate to form the radical.

35. The method of claim 34, wherein the radical has at least one component selected from the group consisting of an alkyl group, an aryl group, a benzyl group, hydrogen and an alkali metal.
